(19) United States
(12) Patent Application Publication
(10) Pub. No.: US 2026/0177613 A1
(43) Pub. Date: Jun. 25, 2026

(54) CLOCK FAULT DETECTION DEVICE AND METHOD

(71) Applicant: Samsung Electronics Co., Ltd., Suwon-si (KR)

(72) Inventors: HYUNSEOK NAM, Suwon-si (KR); Sooyoung Kang, Suwon-si (KR)

(21) Appl. No.: 19/424,433

(22) Filed: Dec. 18, 2025

(30) Foreign Application Priority Data
Dec. 20, 2024 (KR) 10-2024-0192323

(51) Int. Cl. G01R 31/317

(52) U.S. Cl. CPC G01R 31/31726

(57) ABSTRACT

A detection device includes a window clock output circuit configured to output a first window clock having a second period greater than a first period of a common clock, and a second window clock having the second period and delayed by a specific amount of time relative to the first window clock, and a defect detection circuit configured to detect consecutive edges included in the common clock from logic high periods of the first window clock and the second window clock and logic low periods of the first window clock and the second window clock.

### CROSS-REFERENCE TO RELATED APPLICATION(S)

This U.S. non-provisional application claims priority under 35 USC § 119 to Korean Patent Application No. 10-2024-0192323, filed on Dec. 20, 2024, in the Korean Intellectual Property Office, the disclosure of which is herein incorporated by reference in its entirety.

### BACKGROUND

The present disclosure relates to a clock fault detection device and a clock fault detection method.

Due to recent advancements in various technologies, intellectual properties (IPs) such as safety IPs or security IPs, which provide security for critical information such as personal data, may be required. The IPs may be configured to defend against security attacks such as physical attacks and side-channel analysis attacks.

There are various types of security attacks. A clock attack, a prominent type of security attack, targets clocks provided to IPs. For instance, a clock attack includes changes in clock frequency (increase, decrease, or dynamic variation), changes in clock duty, occurrence of glitches for a clock, pulse loss causing omission of certain pulses for a clock, or the like. For example, pulse loss is a type of clock attack that is necessarily examined in automotive semiconductor design.

### SUMMARY

One or more embodiments provide a clock fault detection device and a clock fault detection method for detecting various types of clock faults.

According to one or more embodiment, a detection device includes a window clock output circuit configured to obtain a clock signal having a first signal period and configured to output a first window clock signal having a second signal period, a second window clock signal delayed, by a time delay amount, relative to the first window clock signal and having a signal period equal to the second signal period; a defect detection circuit configured to detect consecutive signal edges of the clock signal using logic high periods and logic low periods of the first and second window clock signals, wherein the second signal period is greater than the first signal period.

According to one or more embodiments, a method of a detection device includes obtaining a clock signal having a first signal period; obtaining a first window clock signal having a second signal period that is greater than the first signal period of the clock signal, and a second window clock signal having a signal period equal to the second signal period, the second window clock signal delayed by a time delay amount relative to the first window clock signal; and detecting consecutive signal edges included in the clock signal using logic high periods and logic low periods of the first and second window clock signals.

According to one or more embodiments, a detection device includes a first detection circuit configured to obtain a clock signal, a first window clock signal, and a second window clock signal, and to detect two consecutive signal edges in the clock signal using logic high periods and logic low periods of the first and second window clock signals; and a second detection circuit configured to obtain the clock signal, the first window clock signal, and the second window clock signal and to detect three or more consecutive signal edges in the clock signal using the logic high periods and the logic low periods of the first and second window clock signals, wherein the clock signal has a first signal period, the first window clock signal has a second signal period, and the second window clock signal has a signal period equal to the second signal period, wherein the second window clock signal is delayed relative to the first window clock signal by a time delay amount, and wherein the second signal period is greater than the first signal period.

### BRIEF DESCRIPTION OF DRAWINGS

FIG. 1 is a block diagram of a detection device according to one or more embodiments.

FIG. 2 is a block diagram of a fault detection circuit according to one or more embodiments.

FIG. 3 is a timing diagram of window clocks according to one or more embodiments.

FIG. 4 is a timing diagram illustrating the definition of delay applied to window clocks according to one or more embodiments.

FIG. 5 is a block diagram of a first detection circuit according to one or more embodiments.

FIG. 6 is a circuit diagram of a first double edge counter according to one or more embodiments.

FIG. 7 is a circuit diagram of a second double edge counter according to one or more embodiments.

FIG. 8 is a circuit diagram of a third double edge counter according to one or more embodiments.

FIG. 9 is a circuit diagram of a fourth double edge counter according to one or more embodiments.

FIG. 10 is a circuit diagram of a first logic circuit according to one or more embodiments.

FIG. 11 is a timing diagram of a pulse loss detection operation during a logic high period of a first detection circuit according to one or more embodiments.

FIG. 12 is a timing diagram of a frequency decrease detection operation during the logic high period of the first detection circuit according to one or more embodiments.

FIG. 13 is a block diagram of a second detection circuit according to one or more embodiments.

FIG. 14 is a circuit diagram of a first triple edge counter according to one or more embodiments.

FIG. 15 is a circuit diagram of a second triple edge counter according to one or more embodiments.

FIG. 16 is a circuit diagram of a third triple edge counter according to one or more embodiments.

FIG. 17 is a circuit diagram of a fourth triple edge counter according to one or more embodiments.

FIG. 18 is a circuit diagram of a fifth triple edge counter according to one or more embodiments.

FIG. 19 is a circuit diagram of a sixth triple edge counter according to one or more embodiments.

FIG. 20 is a circuit diagram of a seventh triple edge counter according to one or more embodiments.

FIG. 21 is a circuit diagram of an eighth triple edge counter according to one or more embodiments.

FIG. 22 is a circuit diagram of a second logic circuit according to one or more embodiments.

FIG. 23 is a timing diagram of a glitch detection operation during a logic high period of the second detection circuit according to one or more embodiments.

FIG. 24 is a flowchart illustrating a method of a detection device according to one or more embodiments.

### DETAILED DESCRIPTION

Hereinafter, example embodiments will be described with reference to the accompanying drawings.

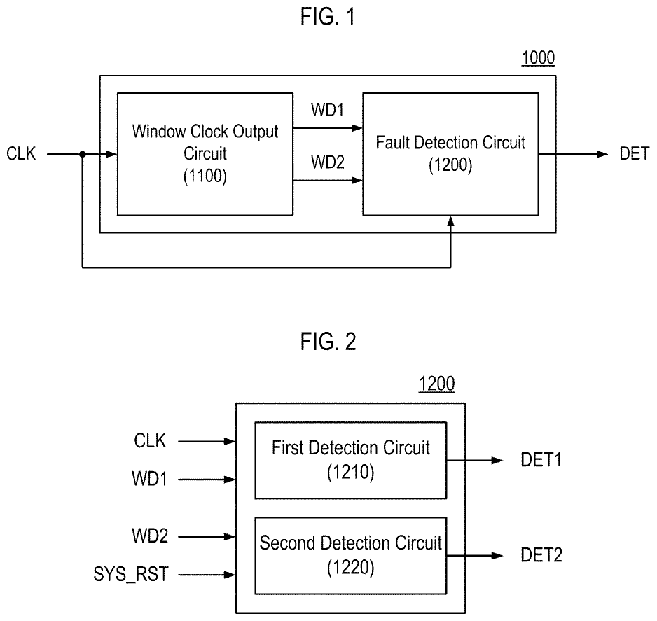

FIG. 1 is a block diagram of a detection device according to one or more embodiments. In the present disclosure, the term “clock”, depending on context, may refer to a periodic signal that, for example, alternates between a logic high level and a logic low level.

Referring to FIG. 1, a detection device 1000 according to one or more embodiments may include a window clock output circuit 1100 and a fault detection circuit 1200.

The window clock output circuit 1100 may be configured to receive a common clock CLK (which may also be referred to as “common clock signal CLK” or “clock signal”) and obtain (or generate) and output a first window clock WD1 (which may also be referred to as first window clock signal WD1) and a second window clock WD2 (which may also be referred to as first window clock signal WD2) from the common clock CLK. In the present disclosure, a ‘window clock’ is a clock or clock signal that can be used to detect consecutive edges from the common clock signal CLK. In addition, when a duty cycle of each window clock is defined as ‘D,’ a duration of a logic high period within a single cycle of each window clock may be referred to as a D period and a duration of a logic low period within the single cycle may be referred to as a 1-D period.

A common clock CLK that is not subject to a clock attack, for example, a normal common clock CLK is provided as an example. When two signal edges (a rising edge and a falling edge) are detected in the common clock CLK during the logic high period or the logic low period of each window clock, the common clock CLK is considered normal. When a number of signal edge(s), other than two, is detected in the common clock CLK during the logic high period or the logic low period of each window clock, the common clock CLK may be considered abnormal.

In examples herein, “period” of a signal may generally refer to a signal period or duration of one complete cycle of the signal, e.g., the shortest amount of time for a signal to repeat. In certain embodiments, when the signal period of the common clock CLK is defined and referred to as a first period, the first window clock WD1 and the second window clock WD2 each may have a signal period, defined and referred to as second period, where the second period may be larger than the first period. For example, both the first window clock WD1 and the second window clock WD2 may have the same second period (or the same frequency). The second period is defined to be larger than the first period, enabling the detection of more than one edge within the window clock.

In certain embodiments, the second period may be defined to be less than twice the first period to detect two edges included in the common clock CLK within the logic high period or the logic low period of each window clock. When the second period is at least twice the first period, three or more edges may be detected from the normal common clock CLK.

In certain embodiments, the second window clock WD2 may be delayed by a specific amount of time compared to the first window clock WD1. For example, there is a phase difference between the first window clock WD1 and the second window clock WD2. According to the above-described embodiment, when the second period is less than twice the first period, the logic high period and the logic low period of each window clock may be smaller than the first period. When there is no delay, two edges may not be detected in both the first window clock WD1 and the second window clock WD2.

Accordingly, the window clock output circuit 1100 may obtain (or generate) the second window clock WD2 by delaying the first window clock WD1 by a specific amount of time, enabling the detection of two edges within at least one window clock.

In certain embodiments, the window clock output circuit 1100 may further include a delay cell (also referred to or considered a “delay circuit”) to obtain (or generate) the second window clock WD2. The delay cell or delay circuit may be configured to receive the first window clock WD1, delay the received WD1 by a specific amount of time, and output the delayed WD1.

The fault detection circuit 1200 may receive the first window clock WD1 and the second window clock WD2 output from the window clock output circuit 1100, along with the common clock CLK. The fault detection circuit 1200 may be configured to detect consecutive edges included in the common clock CLK from the logic high period of the first window clock WD1 and the second window clock WD2s and the logic low period of the first window clock WD1 and the second window clock WD2.

In certain embodiments, the fault detection circuit 1200 may detect various types of faults occurring in the common clock CLK due to clock attacks. For example, faults may include an increase or decrease in the frequency of the common clock CLK, generation of a glitch in the common clock CLK, or pulse loss causing omission of certain pulses for the common clock CLK.

When the frequency of the common clock CLK decreases or pulse loss occurs in the common clock CLK, the fault detection circuit 1200 fails to detect two consecutive edges in both the logic high period of the first window clock WD1 and the logic high period of the second window clock WD2, or fails to detect two consecutive edges in both the logic low period of the first window clock WD1 and the logic low period of the second window clock WD2. For example, when only one edge is detected from all window clocks for any one logic period, the fault detection circuit 1200 may detect that a frequency decrease or pulse loss has occurred in the common clock CLK.

When detecting a frequency decrease or pulse loss in the common clock CLK, the fault detection circuit 1200 may obtain (or generate) and output a detection signal DET indicating that a fault has been detected.

When the frequency of the common clock CLK increases or a glitch occurs in the common clock CLK, the fault detection circuit 1200 may successfully detect three consecutive edges in at least one of the logic high period of the first window clock WD1, the logic high period of the second window clock WD2, the logic low period of the first window clock WD1, or the logic low period of the second window clock WD2. For example, when three consecutive edges are detected in any one of all window clocks or all logic periods, the fault detection circuit 1200 may detect that a frequency increase or glitch has occurred in the common clock CLK.

When detecting a frequency increase or glitch in the common clock CLK, the fault detection circuit 1200 may obtain (or generate) and output a detection signal DET indicating that a fault has been detected.

The detection device 1000 according to the above-described embodiments may detect an increase or decrease in the frequency of the common clock CLK, occurrence of a glitch for the common clock CLK, or pulse loss, based on two window clocks with a phase difference.

FIG. 2 is a block diagram of a fault detection circuit according to one or more embodiments.

Referring to FIG. 2, a fault detection circuit 1200 according to one or more embodiments may include a first detection circuit 1210 and a second detection circuit 1220. The fault detection circuit 1200 may receive a common clock CLK, a first window clock WD1, a second window clock WD2, and a system reset signal SYS_RST. In certain embodiments, the first window clock WD1 and the second window clock WD2 may be provided from the window clock output circuit (see FIG. 1) according to the above-described embodiments. The system reset signal SYS_RST may be commonly applied to flip-flops included in the first detection circuit 1210 and the second detection circuit 1220. The first window clock WD1 and the second window clock WD2 may be reset based on the system reset signal SYS_RST.

The first detection circuit 1210 may be configured to detect the frequency decrease and pulse loss from the common clock CLK. For example, the first detection circuit 1210 may be configured to detect two consecutive edges included in the common clock CLK from the logic high period and logic low period of the first window clock WD1 and the logic high period and logic low period of the second window clock WD2.

The first detection circuit 1210 may obtain (or generate) and output a first detection signal DET1 indicating that the pulse loss or frequency decrease has been detected from the common clock CLK, when at least one of the following conditions is satisfied: a failure to detect two consecutive edges in both the logic high period of the first window clock WD1 and the logic high period of the second window clock WD2, or a failure to detect two consecutive edges in both the logic low period of the first window clock WD1 and the logic low period of the second window clock WD2.

Alternatively, the first detection circuit 1210 may obtain (or generate) and output a first detection signal DET1 indicating that the common clock CLK is normal when the first detection circuit 210 successfully detects two consecutive edges during at least one of the logic high period of the first window clock WD1 or the logic high period of the second window clock WD2, or during at least one of the logic low period of the first window clock WD1 or the logic low period of the second window clock WD2.

In certain embodiments, the first detection signal DET1 may have a specific logic level (for example, logic high or logic low) when indicating a fault, and may have a specific logic level (for example, logic low or logic high) when indicating a normal state.

The second detection circuit 1220 may be configured to detect a frequency increase and a glitch from the common clock CLK. For example, the second detection circuit 1220 may be configured to detect three or more consecutive edges included in the common clock CLK from the logic high period and logic low period of the first window clock WD1 and the logic high period and logic low period of the second window clock WD2.

The second detection circuit 1220 may obtain (or generate) and output a second detection signal DET2 indicating that the glitch or frequency increase has been detected from the common clock CLK when the second detection circuit 1220 successfully detects three consecutive edges during at least one of the logic high period of the first window clock WD1, the logic high period of the second window clock WD2, the logic low period of the first window clock WD1, or the logic low period of the second window clock WD2.

Alternatively, the second detection circuit 1220 may obtain (or generate) and output a second detection signal DET2 indicating that the common clock CLK is normal when three consecutive edges are not detected during any of the window clocks and logic periods.

In certain embodiments, the second detection signal DET2 may have a specific logic level (for example, logic high or logic low) when indicating a fault, and may have a specific logic level (for example, logic low or logic high) when indicating a normal state.

The fault detection circuit 1200 according to the above-described embodiments may detect the frequency decrease and pulse loss of the common clock CLK based on whether two consecutive edges are detected, and may detect the frequency increase and glitch in the common clock CLK based on whether three consecutive edges are detected. As a result, the fault detection circuit 1200 may detect various types of clock faults.

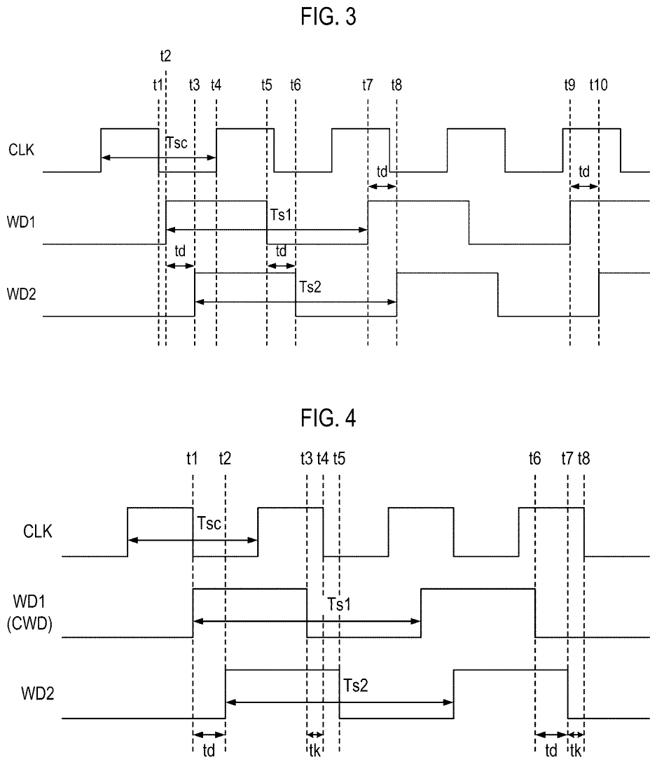

FIG. 3 is a timing diagram of window clocks according to one or more embodiments. Hereinafter, a time point ‘tx’ (where x is a positive integer) is defined as representing an arbitrary time point in each drawing and may be the consistent or vary across drawings.

Referring to FIG. 3, the common clock CLK, the first window clock WD1, and the second window clock WD2 are provided to the fault detection circuit according to the above-described embodiments (see FIG. 1 and FIG. 2). When a signal period of the common clock CLK is denoted as Tsc, a signal period of the first window clock WD1 is defined as Ts1 and a signal period of the second window clock WD2 is defined as Ts2, where Ts1 and Ts2 are the same.

In certain embodiments, periods Ts1 and Ts2 may be defined to be less than twice a value of period Tsc (for example, 2Tsc). For example, periods Ts1 and Ts2 may be defined such that Tsc>Ts1/2 and Tsc>Ts2/2.

When a duty ratio of each window clock is 50%, a length of the logic high period (or logic low period) in a time domain is defined to be less than Tsc. Therefore, two edges may be detected from the logic high period (or logic low period) of at least one window clock.

In certain embodiments, the first window clock WD1 and the second window clock WD2 may have a phase difference. For example, the second window clock WD2 is defined to be delayed by a specific amount of time, time delay td compared to the first window clock WD1. In FIG. 3, an example is provided in which there is a predetermined delay between a falling edge of the common clock CLK at t1 and a rising edge of the first window clock WD1 at t2. In the example, only one rising edge may be detected at t4 during the logic high period of the first window clock WD1. For example, when there is no phase difference between the first window clock WD1 and the second window clock WD2, two consecutive edges are unable to be detected during the logic high period of the second window clock WD2.

According to the above-described embodiments, when there is a time delay td, defined as a period between t2 and t3 or a period between t5 and t6, between the first window clock WD1 and the second window clock WD2, two consecutive edges may be detected within the second window clock WD2 even if two consecutive edges fail to be detected within the first window clock WD1.

As in a period between t7 and t8 and a period between t9 and t10, a delay of a specific amount of time, time delay td, appears uniformly across other cycles.

According to the above-described embodiments, a phase difference between the window clocks may be defined, enabling the detection of two consecutive edges from a normal common clock CLK within at least one window clock.

FIG. 4 is a timing diagram illustrating the definition of delay applied to window clocks according to one or more embodiments. In FIG. 4, the first window clock WD1, which may also be referred to as a comparison window signal CWD. The comparison window signal CWD can define certain parameters or characteristics including, for example, a minimum threshold time tk, and signal periods Ts1 and Ts2. For instance, the comparison window signal CWD can have or define the signal periods Ts1 and Ts2 (which may be equal to Ts1) to be less than 2Tsc (less than two times the expected signal period of the common clock CLK). In addition, the second window clock WD2 can be delayed by a specific amount of time, time delay td, relative to first window clock WD1, which can be equal to the amount of time between t1 and t2.

Referring to FIG. 4, the time delay or time delay amount td according to one or more embodiments may be defined to be greater than a minimum threshold time tk and less than a logic period, e.g., the logic high period or the logic low period. The minimum threshold time tk may be defined as a time between a falling edge included in a first cycle of the common clock CLK (which may be referred to as a “first falling edge”) and another falling edge (which may be referred to as a “second falling edge”) that is closest, in time, to the first falling edge. That is, the second falling edge, may be the falling edge, among a plurality of falling edges included in the comparison window signal CWD (e.g., WD1) that is closest in time to the first falling edge of the common clock signal CLK.

For example, in FIG. 4, the minimum threshold time tk may be defined as an amount of time expiring between t3 and t4. Specifically, at t3 is where the closest, in time, second falling edge of the comparison window signal CWD occurs, with respect to the first falling edge of CLK at t4. Similarly, the minimum threshold time tk may be defined as a period between t7 and t8. In particular, at t7 is where the closest in time second falling edge of the comparison window signal CWD occurs, with respect to a first failing edge at t8.

In at least one example, the comparison window signal CWD, which can indicate or define the minimum threshold time tk, may have a signal period Tsc1 and may be defined to have a rising edge at t1 corresponding to a falling edge (referred to as a third falling edge) included in the common clock CLK.

Alternatively, when the rising edge included in a logic high period of the comparison window signal CWD (referred to as a first logic high period) and the falling edge included in a logic high period of the common clock CLK (referred to as a second logic high period) occur at the same time, the minimum threshold time tk may be defined as a time difference between the falling edge included in the first logic high period and the rising edge included in a third logic high period of the common CLK. The third logic high period is the immediate next in time logic high period of the common CLK, following the second logic high period of the common clock CLK.

In one or more examples described herein, the minimum threshold time tk can be defined between the comparison window signal CWD (or first window clock WD1) and the common clock CLK under normal or expected clock conditions, e.g., when the common clock is not subject to faults or attacks.

The time delay td, may be defined as a period between t1 and t2 or a period between t6 and t7, may be defined to be greater than the minimum threshold time tk defined according to the above-described embodiments. In FIG. 4, at t1 the falling edge of the common clock CLK overlaps the rising edge of the comparison window clock as is the case with WD1 of FIG. 4), this falling edge at t1 of the common clock CLK may fail or be unable to be detected. Therefore, to avoid this, the time delay td may be defined to be greater than the minimum threshold time tk (which is the case with WD2), which allows for the detection of two consecutive edges of the common clock CLK within at least the logic high period between t2 and t5 of the second window clock WD2. When the time delay td is less than the minimum threshold time tk, a falling edge within the logic high period between t2 and t5 of the second window clock WD2 may also fail to be detected.

In addition, the time delay td may be defined to be less than the logic high period or logic low period of each window clock. This is because when the time delay td is greater than a logic high period or a logic low period of the CWD signal, there may also be a logic period, for example, in the second window clock WD2 at which two consecutive signal edges of the common clock CLK fail to be detected. A “signal edge” can refer to either of a rising edge or falling edge of a signal, e.g., common clock CLK.

According to the above-described embodiments, the time delay td may be defined such that tk<td<D or tk<td<1−D, where D is a duration of logic high period of each window clock (e.g., WD1 and WD2) and 1−D is a duration of a logic low period of each window clock.

The time delay td may be defined according to the above-described embodiments, enabling the detection of two consecutive signal edges of the common clock CLK from at least one window clock signal during a normal clock.

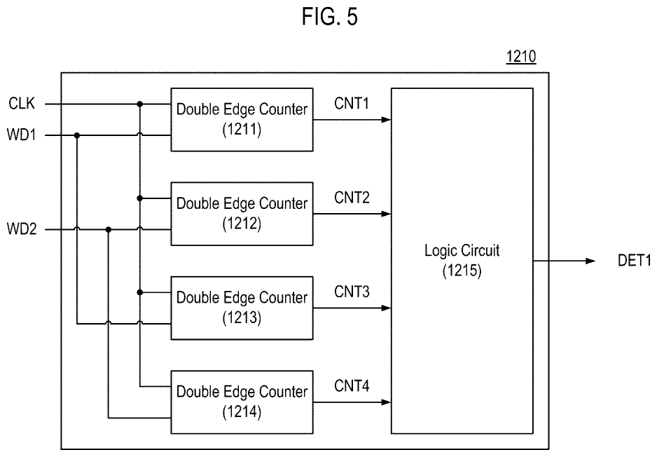

FIG. 5 is a block diagram of a first detection circuit according to one or more embodiments.

Referring to FIG. 5, the first detection circuit 1210 according to one or more embodiments may include first to fourth double edge counters 1211 to 1214 (also referred to as dual-edge counters) and a first logic circuit 1215. A specific time period may be assigned to each of the first to fourth double edge counters 1211 to 1214 to counting two consecutive signal edges of the common clock CLK.

The first double edge counter 1211 may be configured to count two consecutive signal edges of the common clock CLK during the logic high period of the first window clock WD1 based on the common clock CLK and the first window clock WD1. The first double edge counter 1211 may obtain (or generate) and output a first counter signal CNT1 indicating whether two consecutive signal edges of the common clock CLK are counted during the logic high period of the first window clock WD1.

The second double edge counter 1212 may be configured to count two consecutive signal edges of the common clock CLK during the logic high period of the second window clock WD2 based on the common clock CLK and the second window clock WD2. The second double edge counter 1212 may obtain (or generate) and output a second counter signal CNT2 indicating whether two consecutive edges of the common clock CLK are counted during the logic high period of the second window clock WD2.

The third double edge counter 1213 may be configured to count two consecutive edges of the common clock CLK during the logic low period of the first window clock WD1 based on the common clock CLK and the first window clock WD1. The third double edge counter 1213 may obtain (or generate) and output a third counter signal CNT3 indicating whether two consecutive edges of the common clock CLK are counted during the logic low period of the first window clock WD1.

The fourth double edge counter 1214 may be configured to count two consecutive signal edges of the common clock CLK during the logic low period of the second window clock WD2 based on the common clock CLK and the second window clock WD2. The fourth double edge counter 1214 may obtain (or generate) and output a fourth counter signal CNT4 indicating whether two consecutive signal edges of the common clock CLK are counted during the logic low period of the second window clock WD2.

The first logic circuit 1215 may receive the first to fourth counter signals CNT1 to CNT4 from the first to fourth double edge counters 1211 to 1214. The first logic circuit 1215 may check whether two signal edges are detected, based on the first to fourth counter signals CNT1 to CNT4. The first logic circuit 1215 may be configured to output a first detection signal DET1 indicating that a pulse loss or a frequency decrease has been detected from the common clock CLK when or in response to, at least one of the following conditions is satisfied: a failure to detect two consecutive signal edges in both the first and second double edge counters 1211 and 1212, or a failure to detect two consecutive signal edges of the common clock CLK in both the third and fourth double edge counters 1213 and 1214.

The first detection circuit 1210 according to the above-described embodiments may detect the pulse loss and frequency decrease from the common clock CLK.

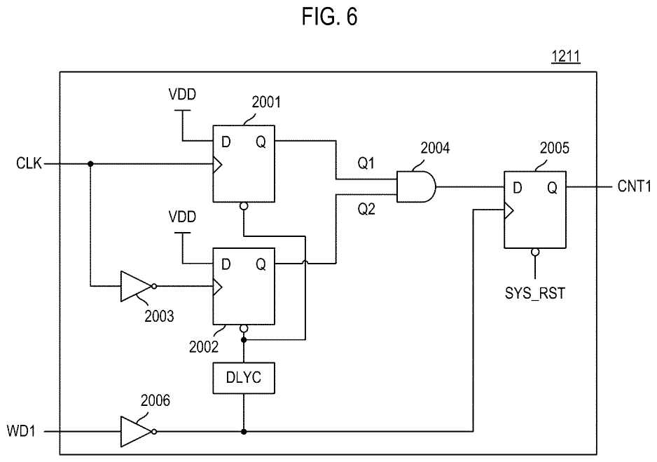

FIG. 6 is a circuit diagram of a first double edge counter according to one or more embodiments. Hereinafter, detailed descriptions of redundant configurations may be omitted. An example is provided in which each flip-flop (e.g., 2001, 2002, 2005) operates based on rising edge triggering and is reset when a logic high is provided to a reset pin (e.g., forcing a low logic at its output), but embodiments are not limited thereto. An example is also provided in which a falling edge of the common clock CLK occurs first in a logic high period of the first window clock WD1.

Referring to FIG. 6, the first double edge counter 1211 may include a first flip-flop 2001, a second flip-flop 2002, a first inverter 2003, an AND gate 2004, a third flip-flop 2005, a second inverter 2006, and a delay cell DLYC.

The first flip-flop 2001 may include a first input pin connected to a supply voltage VDD and may be configured to operate in synchronization with the common clock CLK. For example, the common clock CLK may be provided to a clock pin of the first flip-flop 2001. In other examples, a flip-flop to operate in synchronization with a particular signal can mean that the particular signal is provided to a clock pin of the flip-flop.

The second flip-flop 2002 may include a second input pin connected to a supply voltage and may be configured to operate in synchronization with an inverted version of the common clock CLK. The first inverter 2003 may output the inverted common clock CLK to a clock pin of the second flip-flop 2002.

The AND gate 2004 may be configured to perform an AND operation on outputs of the first flip-flop 2001 and the second flip-flop 2002. The output of the AND gate 2004 may be provided to the third flip-flop 2005.

The second inverter 2006 may output an inverted version of a first window clock WD1 to the third flip-flop 2005 and the delay cell or delay circuit DLYC. The delay cell DLYC may be commonly connected to a first reset pin of the first flip-flop 2001 and a second reset pin of the second flip-flop 2002 and delay the first inverted window clock, provided from the second inverter 2006, by a predetermined (or predefined) amount of time. Thus, the first inverted window clock signal delayed by the predetermined amount of time may be provided to the first reset pin of the first flip-flop 2001 and the second reset pin of the second flip-flop 2002.

The third flip-flop 2005 may include a third input pin connected to the output of the AND gate 2004 and may be configured to operate in synchronization with the first inverted window clock signal. A system reset signal SYS_RST may be provided to the third reset pin of the third flip-flop 2005. A first counter signal CNT1 may be output from an output pin of the third flip-flop 2005.

The operation of the first double edge counter 1211 according to one or more embodiments is as follows.

The first flip-flop 2001 and the second flip-flop 2002 may be reset when a specific logic level (for example, logic high) is applied to reset pins thereof. For instance, the first flip-flop 2001 and the second flip-flop 2002 may be reset during the logic low period of the first window clock WD1, and the first flip-flop 2001 and the second flip-flop 2002 may operate during the logic high period of the first window clock WD1.

With respect to the logic high period of the first window clock WD1, the common clock CLK may be provided while the first flip-flop 2001 and the second flip-flop 2002 are in a reset state. The inverted common clock CLK is provided to the clock pin of the second flip-flop 2002, so that an output Q2 of the second flip-flop 2002 may transition to logic high at a falling edge of the common clock CLK. Then, an output Q1 of the first flip-flop 2001 may transition to logic high at a rising edge of the common clock CLK.

After the rising edge of the common clock CLK, the AND gate 2004 may output logic high to the third input pin. The first inverted window clock is provided to the clock pin of the third flip-flop 2005, so that the third flip-flop 2005 may output the output of the AND gate 2004 as the first counter signal CNT1 when the first window clock WD1 transitions from logic high to logic low.

When a frequency decrease or pulse loss occurs in the common clock CLK, logic low may be output from either the first flip-flop 2001 or the second flip-flop 2002. Thus, the first counter signal CNT1 may indicate that two consecutive signal edges of the common clock CLK have not been counted.

When the logic high period of the first window clock WD1 ends, the first flip-flop 2001 and the second flip-flop 2002 may be reset after a predetermined amount of time delay through the delay cell DLYC. By applying the predetermined/predefined amount of time delay to the first inverted window clock, the delay cell DLYC may prevent the first counter signal CNT1 from indicating an incorrect detection result.

In certain embodiments, the above-described system reset signal SYS_RST may also be provided to the first flip-flop 2001 and the second flip-flop 2002. The first window clock WD1 and the second window clock WD2 may be reset based on the system reset signal SYS_RST.

According to the above-described embodiments, the first double edge counter 1211 may detect two edges in the logic high period of the first window clock WD1.

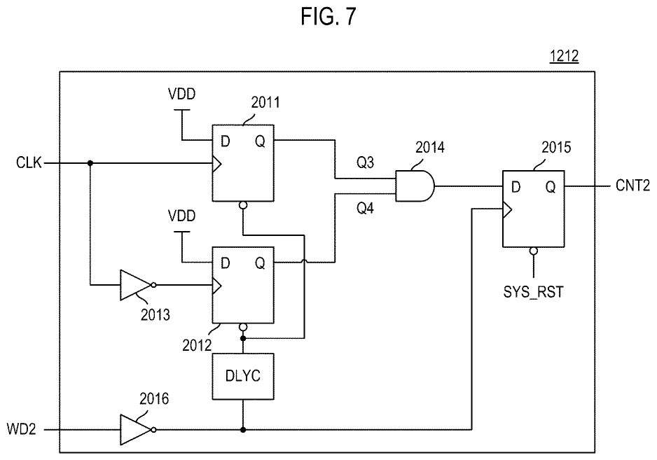

FIG. 7 is a circuit diagram of a second double edge counter according to one or more embodiments.

Referring to FIG. 7, the second double edge counter 1212 may include a first flip-flop 2011, a second flip-flop 2012, a first inverter 2013, an AND gate 2014, a third flip-flop 2015, a second inverter 2016, and a delay cell DLYC.

In the second double edge counter 1212, the second window clock WD2 may be provided to the second inverter 2016 for operation during the logic high period of the second window clock WD2. The second inverter 2016 may output an inverted version of the second window clock WD2 to the third flip-flop 2015 and the delay cell DLYC. The delay cell DLYC may delay the second inverted window clock provided from the second inverter 2016 by a predetermined amount of time.

The third flip-flop 2015 may be configured to operate in synchronization with the second inverted window clock. A system reset signal SYS_RST may be provided to the third reset pin of the third flip-flop 2015. The second counter signal CNT2 may be output from the output pin of the third flip-flop 2015.

The operation of the second double edge counter 1212 according to one or more embodiments is as follows.

The first flip-flop 2011 and the second flip-flop 2012 may be reset during the logic low period of the second window clock WD2, and the first flip-flop 2011 and the second flip-flop 2012 may operate during the logic high period of the second window clock WD2.

The inverted common clock CLK is provided to a clock pin of the second flip-flop 2012, so that an output Q4 of the second flip-flop 2012 may transition to logic high at the falling edge of the common clock CLK. Then, an output Q3 of the first flip-flop 2011 may transition to logic high at the rising edge of the common clock CLK.

After the rising edge of the common clock CLK, the AND gate 2014 may output logic high to the third input pin. The second inverted window clock is provided to the clock pin of the third flip-flop 2015, so that the third flip-flop 2015 may output the output of the AND gate 2014 as the second counter signal CNT2 when the second window clock WD2 transitions from logic high to logic low. When a frequency decrease or pulse loss occurs in the common clock CLK, the second counter signal CNT2 may indicate that two consecutive signal edges of the common clock CLK have not been counted.

When the logic high period of the second window clock WD2 ends, the first flip-flop 2011 and the second flip-flop 2012 may be reset after a predetermined amount of time delay through the delay cell DLYC.

In certain embodiments, the above-described system reset signal SYS_RST may also be provided to the first flip-flop 2011 and the second flip-flop 2012. The first window clock WD1 and the second window clock WD2 may be reset based on the system reset signal SYS_RST.

According to the above-described embodiments, the second double edge counter 1212 may detect two edges during the logic high period of the second window clock WD2.

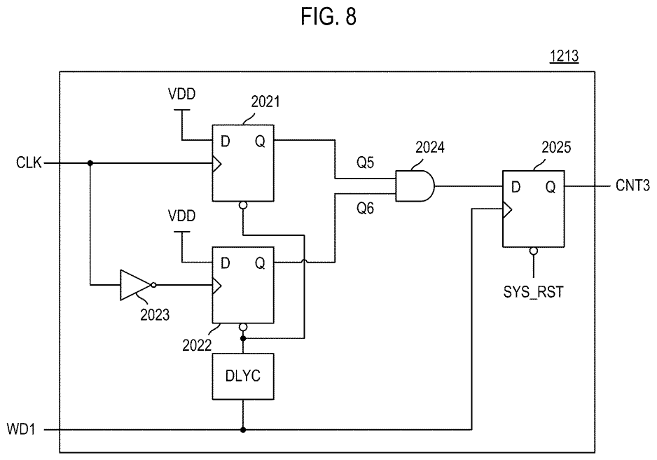

FIG. 8 is a circuit diagram of a third double edge counter according to one or more embodiments.

Referring to FIG. 8, the third double edge counter 1213 may include a first flip-flop 2021, a second flip-flop 2022, a first inverter 2023, an AND gate 2024, a third flip-flop 2025, and a delay cell DLYC. The second inverter of FIG. 6 and FIG. 7 is omitted from the third double edge counter 1213.

In the third double edge counter 1213, the first window clock WD1 may be provided, without inversion, to the third flip-flop 2025 and the delay cell DLYC for operation during the logic low period of the first window clock WD1. The delay cell DLYC may delay the first window clock WD1 by a predetermined amount of time.

The third flip-flop 2025 may be configured to operate in synchronization with the first window clock WD1. A system reset signal SYS_RST may be provided to a third reset pin of the third flip-flop 2025. The third counter signal CNT3 may be output from an output pin of the third flip-flop 2025.

The operation of the third double edge counter 1213 according to one or more embodiments is as follows.

The first window clock WD1 are provided to reset pins of the first flip-flop 2021 and the second flip-flop 2022 through the delay cell DLYC without inversion, so that the first flip-flop 2021 and the second flip-flop 2022 may be reset during the logic high period of the first window clock WD1. The first flip-flop 2021 and the second flip-flop 2022 may operate during the logic low period of the first window clock WD1.

An inverted common clock CLK is provided to a clock pin of the second flip-flop 2022, so that an output Q5 of the second flip-flop 2022 may transition to logic high at a falling edge of the common clock CLK. Then, an output Q6 of the first flip-flop 2021 may transition to logic high at a rising edge of the common clock CLK.

After the rising edge of the common clock CLK, the AND gate 2024 may output logic high to a third input pin. The first window clock WD1 is provided to the clock pin of the third flip-flop 2025, so that the third flip-flop 2025 may output the output of the AND gate 2024 as the third counter signal CNT3 when the first window clock WD1 transitions from logic low to logic high. When a frequency decrease or pulse loss occurs in the common clock CLK, the third counter signal CNT3 may indicate that two consecutive signal edges of the common clock CLK have not been counted.

When the logic low period of the first window clock WD1 ends, the first flip-flop 2021 and the second flip-flop 2022 may be reset after a predetermined amount of time delay through the delay cell DLYC.

In certain embodiments, the above-described system reset signal SYS_RST may also be provided to the first flip-flop 2021 and the second flip-flop 2022. The first window clock WD1 and the second window clock WD2 may be reset based on the system reset signal SYS_RST.

According to the above-described embodiments, the third double edge counter 1213 may detect two edges during the logic low period of the first window clock WD1.

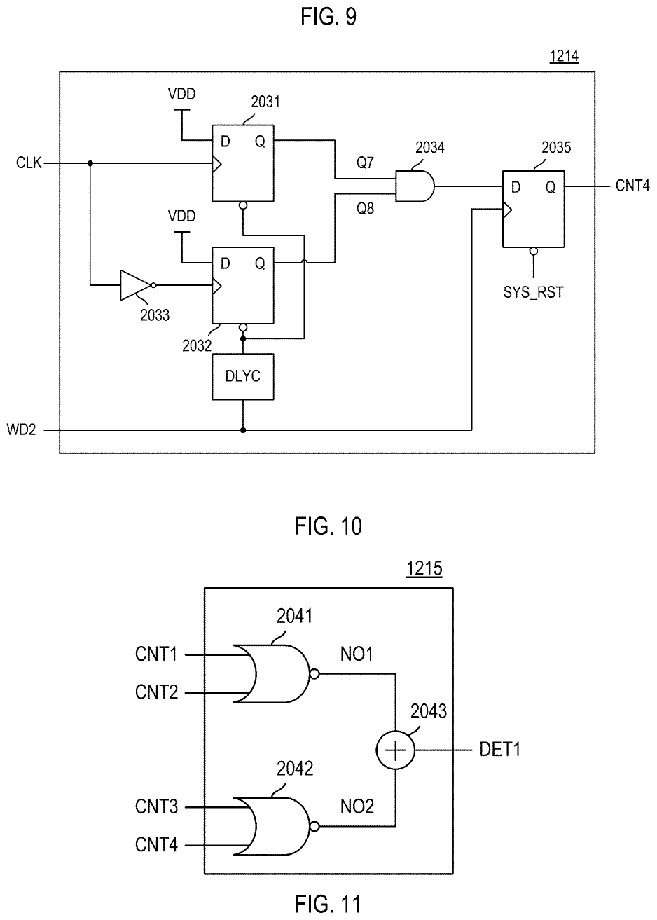

FIG. 9 is a circuit diagram of a fourth double edge counter according to one or more embodiments.

Referring to FIG. 9, the fourth double edge counter 1214 may include a first flip-flop 2031, a second flip-flop 2032, a first inverter 2033, an AND gate 2034, a third flip-flop 2035, and a delay cell DLYC. The second inverter of FIG. 6 and FIG. 7 is omitted from the fourth double edge counter 1214.

In the fourth double edge counter 1214, the second window clock WD2 may be provided, without inversion, to the third flip-flop 2035 and the delay cell DLYC for operation during the logic low period of the second window clock WD2. A delay cell/delay circuit DLYC may delay the second window clock WD2 by a predetermined/predefined amount of time.

The third flip-flop 2035 may be configured to operate in synchronization with the second window clock WD2. A system reset signal SYS_RST may be provided to a third reset pin of the third flip-flop 2035. The fourth counter signal CNT4 may be output from an output pin of the third flip-flop 2035.

The operation of the fourth double edge counter 1214 according to one or more embodiments is as follows.

The second window clock WD2 is provided, without inversion, to reset pins of the first flip-flop 2031 and the second flip-flop 2032 through the delay cell DLYC, so that the first flip-flop 2031 and the second flip-flop 2032 may be reset during the logic high period of the second window clock WD2. The first flip-flop 2031 and the second flip-flop 2032 may operate during the logic low period of the second window clock WD2.

An inverted common clock CLK is provided to the clock pin of the second flip-flop 2032, so that an output Q7 of the second flip-flop 2032 may transition to logic high at a falling edge of the common clock CLK. Then, an output Q8 of the first flip-flop 2031 may transition to logic high at a rising edge of the common clock CLK.

After the rising edge of the common clock CLK, the AND gate 2034 may output a logic high to the third input pin. The second window clock WD2 is provided to a clock pin of the third flip-flop 2035, so that the third flip-flop 2035 may output the output of the AND gate 2034 as the fourth counter signal CNT4 when the second window clock WD2 transitions from logic low to logic high. When a frequency decrease or pulse loss occurs in the common clock CLK, the fourth counter signal CNT4 may indicate that two consecutive signal edges of the common clock CLK have not been counted.

When the logic low period of the second window clock WD2 ends, the first flip-flop 2031 and the second flip-flop 2032 may be reset after a predetermined amount of time delay through the delay cell DLYC.

In certain embodiments, the above-described system reset signal SYS_RST may also be provided to the first flip-flop 2031 and the second flip-flop 2032. The first window clock WD1 and the second window clock WD2 may be reset based on the system reset signal SYS_RST.

According to the above-described embodiments, the fourth double edge counter 1214 may detect two edges during the logic low period of the second window clock WD2.

FIG. 10 may be a circuit diagram of a first logic circuit according to one or more embodiments.

Referring to FIG. 10, the first logic circuit 1215 according to one or more embodiments may include a first NOR gate 2041, a second NOR gate 2042, and an OR operator 2043.

The first NOR gate 2041 may receive the first counter signal CNT1 and the second counter signal CNT2 and perform a NOR operation on the first counter signal CNT1 and the second counter signal CNT2. The second NOR gate 2042 may receive a third counter signal CNT3 and a fourth counter signal CNT4 and perform a NOR operation on the third counter signal CNT3 and the fourth counter signal CNT4. The first to fourth counter signals CNT1 to CNT4 may indicate that a frequency decrease or pulse loss has occurred from the common clock CLK, at a specific logic level (for example, logic high).

When the specific logic level is high, an output NO1 of the first NOR gate 2041 may indicate logic low only when two consecutive signal edges of the common clock CLK fail to be detected in both the first counter signal CNT1 and the second counter signal CNT2. Similarly, an output NO2 of the second NOR gate 2042 may indicate logic low only when two consecutive signal edges of the common clock CLK fail to be detected in both the third counter signal CNT3 and the fourth counter signal CNT4.

The OR operator 2043 may output a first detection signal DET1 indicating that a fault has occurred when at least one of the first NOR gate 2041 or the second NOR gate 2042 outputs a logic high (for example, when a fault is detected during at least one of the logic high period or the logic low period).

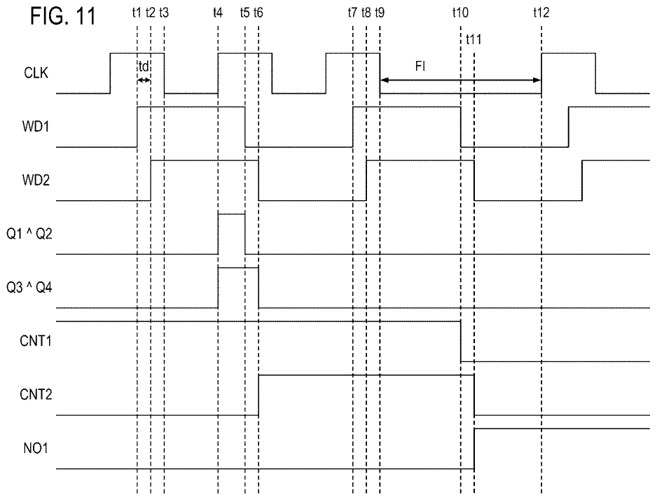

FIG. 11 is a timing diagram of a pulse loss detection operation in a logic high period of the first detection circuit according to one or more embodiments. In FIG. 11, a first double edge counter 1211 corresponds to the one illustrated in FIG. 6, and the second double edge counter 1212 corresponds to the one illustrated in FIG. 7.

Referring to FIG. 6, FIG. 7, FIG. 10, and FIG. 11, a delay of td, defined as the period between t1 and t2, may be applied between the first window clock WD1 and the second window clock WD2.

A detection of a normally operating common clock CLK is described. Two consecutive signal edges of the common clock CLK are present in both the logic high period of the first window clock WD1 corresponding to a period from t1 to t5 and the logic high period of the second window clock WD2 corresponding to a period from t2 to t6.

The reset state of the first double edge counter 1211 may be released during a period from t1 to t5, and the reset state of the second double edge counter 1212 may be released during a period from t2 to t6.

At t3 at which a falling edge of the common clock CLK occurs, Q2 and Q4 may transition to logic high.

At t4 at which a rising edge of the common clock CLK occurs, Q1 and Q3 may transition to logic high.

After t4, an AND operation output Q1\hat{ }Q2 of Q1 and Q2 and an AND operation output Q3\hat{ }Q4 of Q3 and Q4 may transition to a logic high. Therefore, the first counter signal CNT1 may be maintained at an existing logic high level. Since the period (corresponding to the first counter signal CNT) is a logic high, the second counter signal CNT2 may output a logic low. The output NO1 of the first NOR gate may output a logic low based on to the NOR operation.

The first double edge counter 1211 may be reset during t5 to t7 (e.g., forcing a logic low at its output), and the second double edge counter 1212 may be reset during t6 to t8 (e.g., forcing logic low at its output). A fault interval FI with pulse loss in the common clock CLK may occur during a period from t9 to t12.

The reset state of the first double edge counter 1211 may be released again during a period from t7 to t10, and the reset state of the second double edge counter 1212 may be released again during a period from t8 to t11.

At t9 at which the falling edge of the common clock CLK occurs, Q2 and Q4 may transition to logic high.

No edge is present during the fault interval FI, so that Q1 and Q3 fail to transition to logic high after the release of the reset state and output logic low. Accordingly, both the AND operation output Q1\hat{ }Q2 of Q1 and Q2 and the AND operation output Q3\hat{ }Q4 of Q3 and Q4 may output logic low.

At t10, the first counter signal CNT1 synchronized with the falling edge may transition to logic low. Similarly, at t11, the second counter signal CNT2 synchronized with the falling edge may transition to logic low. Thus, after t11 at which both the first counter signal CNT1 and the second counter signal CNT2 are low, the output NO1 of the first NOR gate, indicating whether a glitch is detected during the logic high period, may become logic high based on the NOR operation.

As illustrated in the drawing, the first detection circuit 1210 according to one or more embodiments may detect a fault within a single cycle of the window clocks.

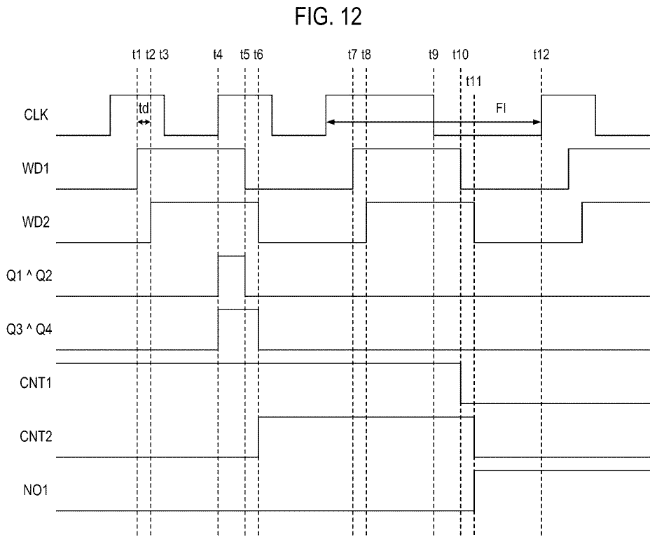

FIG. 12 is a timing diagram of the frequency decrease detection operation in the logic high period of the first detection circuit according to one or more embodiments. In FIG. 12, a first double edge counter 1211 corresponds to the one illustrated in FIG. 6, and the second double edge counter 1212 corresponds to the one illustrated in FIG. 7. In addition, a detailed description of operations redundant to those in FIG. 11 is omitted.

Referring to FIG. 6, FIG. 7, FIG. 10, and FIG. 12, a delay of td, defined as a period between t1 and t2, may be applied between the first window clock WD1 and the second window clock WD2.

Two consecutive signal edges of the common clock CLK are present in both the logic high period of the first window clock WD1 corresponding to a period from t1 to t5 and the logic high period of the second window clock WD2 corresponding to a period from t2 to t6. Therefore, the first counter signal CNT1, indicating whether edges are detected during the logic high period, may be high.

Then, the first double edge counter 1211 may be reset during a period from t5 to t7, and the second double edge counter 1212 may be reset during a period from t6 to t8. A fault interval FI with a frequency decrease in the common clock CLK may occur during a period from t9 to t12.

The reset state of the first double edge counter 1211 may be released again during a period from t7 to t10, and the reset state of the second double edge counter 1212 may be released again during a period from t8 to t11.

At t9 at which the falling edge of the common clock CLK occurs, Q2 and Q4 transition to logic high. Due to the frequency decrease in the fault interval FI, the falling edge of the common clock CLK may be delayed compared to a time point expected based on the original frequency.

No rising edge is present during a period from t9 to t12, so that Q1 and Q3 fail to transition to logic high after the release of the reset state and output logic low. Accordingly, both an AND operation output Q1\hat{ }Q2 of Q1 and Q2 and an AND operation output Q3\hat{ }Q4 of Q3 and Q4 may output logic low.

The first counter signal CNT1, synchronized with the falling edge, may transition to logic low at t10, and the second counter signal CNT2 may transition to logic low at t11. Thus, after t11, the output NO1 of the first NOR gate, which indicates whether a fault is detected during the logic high period, may become logic high based on the NOR operation.

As illustrated in the drawing, the first detection circuit 1210 according to one or more embodiments may detect a fault within a single cycle of the window clocks.

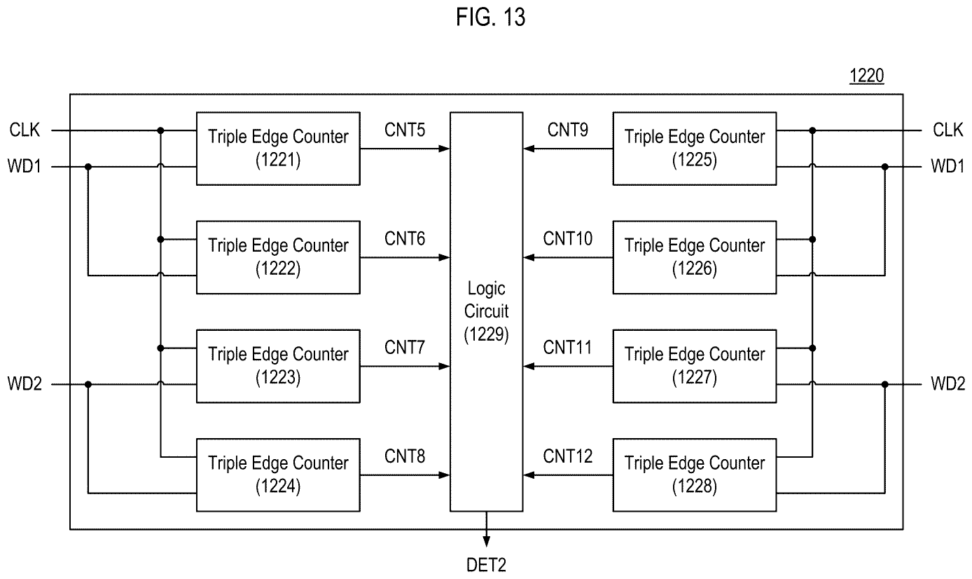

FIG. 13 may be a block diagram of a second detection circuit according to one or more embodiments.

Referring to FIG. 13, the second detection circuit 1220 according to one or more embodiments may include first to eighth triple edge counters 1221 to 1228 and a second logic circuit 1229. A specific time or period for counting three consecutive signal edges of the common clock CLK may be assigned to each of the first to eighth triple edge counters 1221 to 1228.

The first triple edge counter 1221 and the second triple edge counter 1222 may be configured to detect three or more consecutive signal edges of the common clock CLK in or during a logic high period of a first window clock WD1. Based on a common clock CLK and the first window clock WD1, the first triple edge counter 1221 and the second triple edge counter 1222 may obtain (or generate) and output a fifth counter signal CNT5 and a sixth counter signal CNT6, respectively, indicating whether three consecutive signal edges of the common clock CLK are counted in the logic high period of the first window clock WD1.

The third triple edge counter 1223 and the fourth triple edge counter 1224 may be configured to detect three or more consecutive signal edges of the common clock CLK in a logic high period of a second window clock WD2. Based on the common clock CLK and the second window clock WD2, the third triple edge counter 1223 and the fourth triple edge counter 1224 may obtain (or generate) and output a seventh counter signal CNT7 and an eighth counter signal CNT8, respectively, indicating whether three consecutive signal edges of the common clock CLK are counted in the logic high period of the second window clock WD2.

The fifth triple edge counter 1225 and the sixth triple edge counter 1226 may be configured to count three or more consecutive signal edges of the common clock CLK in a logic low period of the first window clock WD1. Based on the common clock CLK and the first window clock WD1, the fifth triple edge counter 1225 and the sixth triple edge counter 1226 may obtain (or generate) and output a ninth counter signal CNT9 and a tenth counter signal CNT10, respectively, indicating whether three consecutive signal edges of the common clock CLK are counted in the logic low period of the first window clock WD1.

The seventh triple edge counter 1227 and the eighth triple edge counter 1228 may be configured to count three or more consecutive signal edges of the common clock CLK in the logic low period of the second window clock WD2. Based on the common clock CLK and the second window clock WD2, the seventh triple edge counter 1227 and the eighth triple edge counter 1228 obtain (or generate) and output an eleventh counter signal CNT11 and a twelfth counter signal CNT12, respectively, indicating whether three signal consecutive edges of the common clock CLK are counted in the logic low period of the second window clock WD2.

The occurrence of a glitch or frequency increase in the common clock CLK refers to the generation of an additional pulse. Therefore, unlike the first detection circuit 1210 configured to detect two consecutive signal edges of the common clock CLK, the second detection circuit 1220 may be configured to detect three consecutive signal edges of the common clock CLK. The additional pulse may be included in a sequence of consecutive logic high, logic low, and logic high, or a sequence of consecutive logic low, logic high, and logic low in the common clock CLK.

The first triple edge counter 1221, the third triple edge counter 1223, the fifth triple edge counter 1225, and the seventh triple edge counter 1227 may be configured to detect an additional pulse included in a sequence of consecutive logic high, logic low, and logic high of the common clock CLK, when a glitch or frequency increase occurs in the common clock CLK. The second triple edge counter 1222, the fourth triple edge counter 1224, the sixth triple edge counter 1226, and the eighth triple edge counter 1228 may be configured to detect an additional pulse including a sequence of consecutive logic low, logic high, and logic low of the common clock CLK when a glitch or frequency increase occurs in the common clock CLK.

The second logic circuit 1229 may receive the fifth to twelfth counter signals CNT5 to CNT12 from the first to eighth triple edge counters 1221 to 1228. The second logic circuit 1229 may check whether at least one of the first to eighth triple edge counters 1221 to 1228 has successfully detected three consecutive signal edges of the common clock CLK, based on the fifth to twelfth counter signals CNT5 to CNT12. When the detection is successful, the second logic circuit 1229 may output a second detection signal DET2 indicating that a glitch or frequency increase has been detected from the common clock CLK.

The second detection circuit 1220 according to the above-described embodiments may detect a glitch and frequency increases from the common clock CLK.

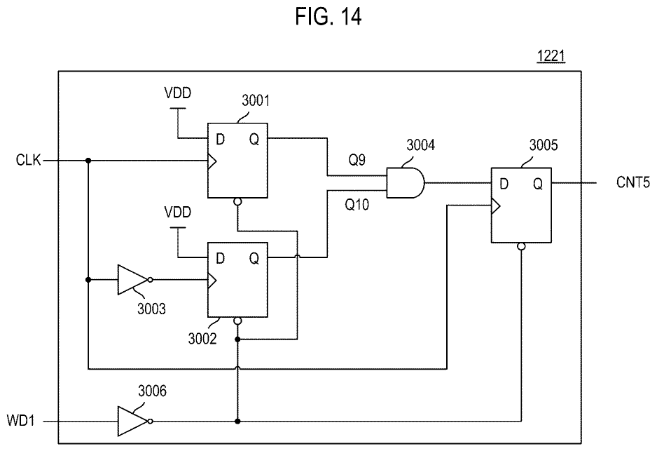

FIG. 14 is a circuit diagram of a first triple edge counter according to one or more embodiments.

Referring to FIG. 14, the first triple edge counter 1221 may include a first flip-flop 3001, a second flip-flop 3002, a first inverter 3003, an AND gate 3004, a third flip-flop 3005, and a fourth inverter 3006.

The first flip-flop 3001 may include a first input pin connected to a supply voltage and may be configured to operate in synchronization with a common clock CLK or an inverted version of the common clock CLK. The second flip-flop 3002 may include a second input pin connected to a supply voltage and may be configured to operate in synchronization with the common clock CLK or the inverted common clock CLK. The first inverter 3003 may output the inverted common clock CLK to the second flip-flop 3002.

The AND gate 3004 may be configured to perform an AND operation on the outputs of the first flip-flop 3001 and the second flip-flop 3002. The output of the AND gate 3004 may be provided to the third flip-flop 3005.

The third flip-flop 3005 may include a third input pin connected to the output of the AND gate 3004 and may be configured to operate in synchronization with the common clock CLK. The fifth counter signal CNT5 may be output from the output pin of the third flip-flop 3005.

The fourth inverter 3006 may output an inverted version of the first window clock WD1 to a first reset pin of the first flip-flop 3001, a second reset pin of the second flip-flop 3002, and a third reset pin of the third flip-flop 3005. Thus, each flip-flop may be reset based on the first inverted window clock.

The operation of the first triple edge counter 1221 according to one or more embodiments is as follows.

The first to third flip-flops 3001, 3002, and 3005 may be reset in a logic low period of the first window clock WD1.

From the logic high period of the first window clock WD1 during which the reset is released, an output Q10 of the second flip-flop 3002 may transition to logic high at the falling edge of the common clock CLK. Then, an output Q9 of the first flip-flop 3001 may transition to logic high at the rising edge of the common clock CLK.

After the rising edge of the common clock CLK, the AND gate 3004 may output logic high to the third input pin. The common clock CLK is provided to the clock pin of the third flip-flop 3005, so that the third flip-flop 3005 may output the output of the AND gate 3004 as the fifth counter signal CNT5 at the next rising edge.

When a frequency increase or glitch occurs in the common clock CLK, logic high may be output from both the first flip-flop 3001 and the second flip-flop 3002. Thus, the first counter signal CNT1 may indicate that three consecutive signal edges of the common clock CLK have been counted.

According to the above-described embodiments, the first triple edge counter 1221 may detect three signal edges of the common clock CLK corresponding to consecutive logic high, logic low, and logic high in the logic high period of the first window clock WD1.

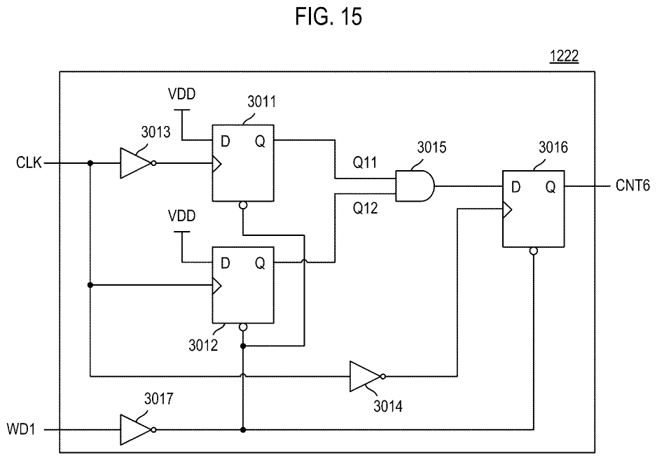

FIG. 15 is a circuit diagram of a second triple edge counter according to one or more embodiments.

Referring to FIG. 15, the second triple edge counter 1222 may include a first flip-flop 3011, a second flip-flop 3012, a second inverter 3013, a third inverter 3014, an AND gate 3015, a third flip-flop 3016, and a fourth inverter 3017.

The second inverter 3013 may output an inverted common clock CLK to the first flip-flop 3011, and the third inverter 3014 may output the inverted common clock CLK to the third flip-flop 3016. Thus, the first flip-flop 3011 and the third flip-flop 3016 operate in synchronization with the inverted common clock CLK.

The operation of the second triple edge counter 1222 according to one or more embodiments is as follows.

The first, second, and third flip-flops 3011, 3012, and 3016 may be reset in a logic low period of a first window clock WD1.

From the logic high period of the first window clock WD1 during which the reset is released, an output Q11 of the first flip-flop 3011 may transition to logic high at the falling edge of the common clock CLK. An output Q12 of the second flip-flop 3012 is logic low, so that the third flip-flop 3016 may output logic low.

Then, an output Q12 of the second flip-flop 3012 may transition to logic high at the rising edge of the common clock CLK. After the rising edge of the common clock CLK, the AND gate 3015 may output logic high to the third input pin. The third flip-flop 3016 may output the output of the AND gate 3015 as a sixth counter signal CNT6 at the next falling edge. The sixth counter signal CNT6 may indicate that three signal edges of the common clock CLK corresponding to consecutive logic low, logic high, and logic low have been detected.

According to the above-described embodiments, the second triple edge counter 1222 may detect three signal edges of the common clock CLK corresponding to consecutive logic low, logic high, and logic low during the logic high period of the first window clock WD1.

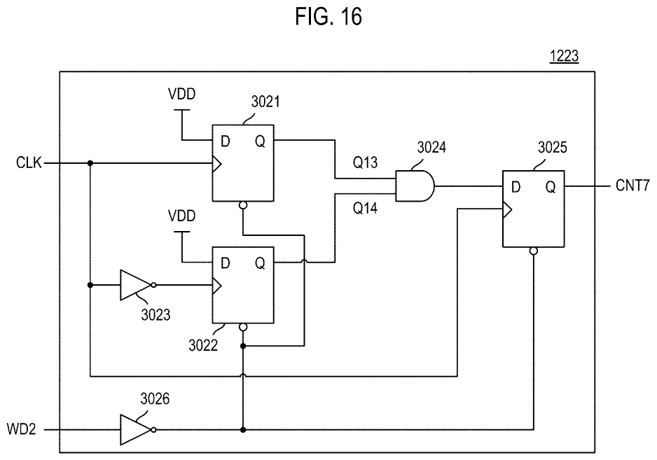

FIG. 16 may be a circuit diagram of a third triple edge counter according to one or more embodiments.

Referring to FIG. 16, the third triple edge counter 1223 according to one or more embodiments may include a first flip-flop 3021, a second flip-flop 3022, a first inverter 3023, an AND gate 3024, a third flip-flop 3025, and a fourth inverter 3026.

The fourth inverter 3026 may output an inverted version of a second window clock WD2 to the first reset pin of the first flip-flop 3021, the second reset pin of the second flip-flop 3022, and the third reset pin of the third flip-flop 3025. Thus, each flip-flop may be reset based on the second inverted window clock.

The operation of the third triple edge counter 1223 according to one or more embodiments may be the same as that of the first triple edge counter 1221 during a logic high period of the second window clock WD2.

The first, second, and third flip-flops 3021, 3022, and 3025 may be reset during the logic low period of the second window clock WD2.

From the logic high period of the second window clock WD2 during which the reset is released, Q14 may transition to logic high at a falling edge of the common clock CLK. Then, Q13 may transition to logic high at a rising edge of the common clock CLK.

After the rising edge of the common clock CLK, the AND gate 3024 may output logic high to a third input pin, and the third flip-flop 3025 may output the output of the AND gate 3024 as a seventh counter signal CNT7 at the next rising edge.

According to the above-described embodiments, the third triple edge counter 1223 may detect three edges corresponding to consecutive logic high, logic low, and logic high during the logic high period of the second window clock WD2.

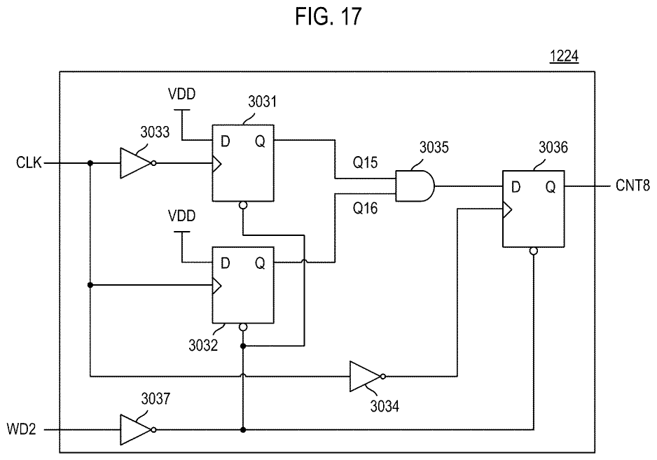

FIG. 17 may be a circuit diagram of a fourth triple edge counter according to one or more embodiments.

Referring to FIG. 17, the fourth triple edge counter 1224 according to one or more embodiments may include a first flip-flop 3031, a second flip-flop 3032, a second inverter 3033, a third inverter 3034, an AND gate 3035, a third flip-flop 3036, and a fourth inverter 3037.

The second inverter 3033 may output an inverted common clock CLK to the first flip-flop 3031, and the third inverter 3034 may output the inverted common clock CLK to the third flip-flop 3036. The fourth inverter 3037 may output the second inverted window clock to the first reset pin of the first flip-flop 3031, the second reset pin of the second flip-flop 3032, and the third reset pin of the third flip-flop 3036. Thus, each flip-flop may be reset based on the second inverted window clock.

The operation of the fourth triple edge counter 1224 according to one or more embodiments may be the same as that of the second triple edge counter 1222 during the logic low period of the second window clock WD2.

The first, second, and third flip-flops 3031, 3032, and 3036 may be reset during the logic low period of the second window clock WD2.

From the logic high period of the second window clock WD2 during which the reset is released, an output Q15 of the first flip-flop 3031 may transition to logic high at the falling edge of the common clock CLK.

Then, an output Q16 of the second flip-flop 3032 may transition to logic high at the rising edge of the common clock CLK. After the rising edge of the common clock CLK, the AND gate 3035 may output logic high to the third input pin. The third flip-flop 3036 may output the output of the AND gate 3035 as an eighth counter signal CNT8 at the next falling edge. The eighth counter signal CNT8 may indicate that three edges corresponding to consecutive logic low, logic high, and logic low have been detected.

According to the above-described embodiments, the fourth triple edge counter 1224 may detect three edges corresponding to consecutive logic low, logic high, and logic low during the logic high period of the second window clock WD2.

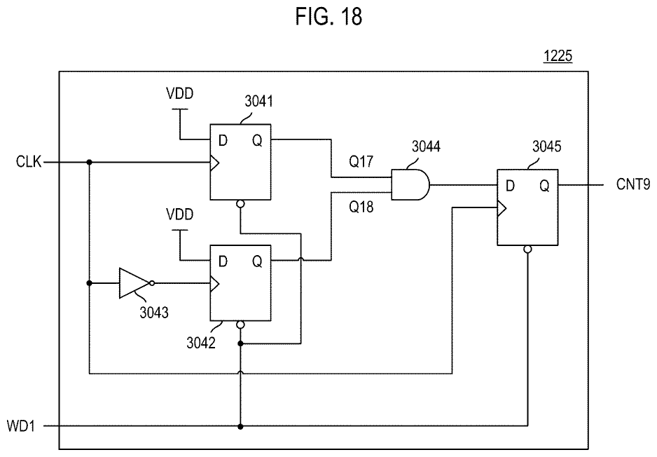

FIG. 18 may be a circuit diagram of a fifth triple edge counter according to one or more embodiments.

Referring to FIG. 18, the fifth triple edge counter 1225 according to one or more embodiments may include a first flip-flop 3041, a second flip-flop 3042, a first inverter 3043, an AND gate 3044, and a third flip-flop 3045.

The first window clock WD1 may be applied, without inversion, to a first reset pin of the first flip-flop 3041, a second reset pin of the second flip-flop 3042, and a third reset pin of the third flip-flop 3045 included in the fifth triple edge counter 1225. Thus, the first, second, and third flip-flops 3041, 3042, and 3045 may be reset based on the first window clock WD1.

The operation of the fifth triple edge counter 1225 according to one or more embodiments is as follows.

The first, second, and third flip-flops 3041, 3042, and 3045 may be reset during the logic high period of the first window clock WD1.

From the logic low period of the first window clock WD1 during the reset is released, an output Q18 of the second flip-flop 3042 may transition to logic high at the falling edge of the common clock CLK. Then, an output Q17 of the first flip-flop 3041 may transition to logic high at the rising edge of the common clock CLK.

After the rising edge of the common clock CLK, the AND gate 3044 may output logic high to the third input pin, and the third flip-flop 3045 may output the output of the AND gate 3044 as a ninth counter signal CNT9 at the next rising edge.

According to the above-described embodiments, the fifth triple edge counter 1225 may detect three edges corresponding to consecutive logic high, logic low, and logic high during the logic low period of the first window clock WD1.

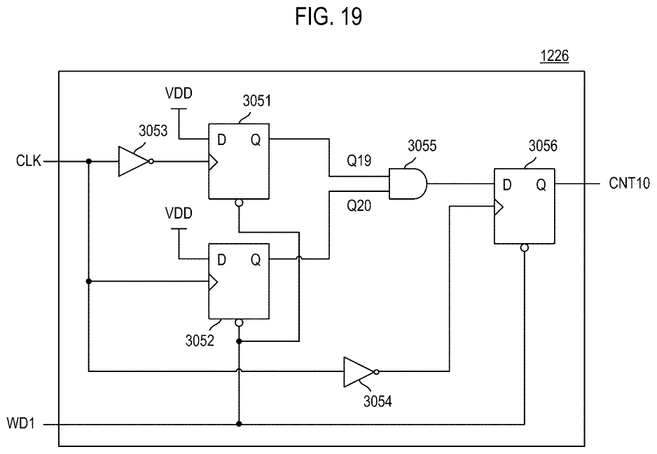

FIG. 19 may be a circuit diagram of a sixth triple edge counter according to one or more embodiments.

Referring to FIG. 19, the sixth triple edge counter 1226 according to one or more embodiments may include a first flip-flop 3051, a second flip-flop 3052, a second inverter 3053, a third inverter 3054, an AND gate 3055, and a third flip-flop 3056.

Due to the second inverter 3053 and the third inverter 3054, each flip-flop may be synchronized with the inverted common clock CLK. The first window clock WD1 may be provided, without inversion, to a reset pin of each flip-flop included in the sixth triple edge counter 1226. Thus, each flip-flop may be reset based on the first window clock WD1.

The operation of the sixth triple edge counter 1226 according to one or more embodiments is as follows.

The first, second, and third flip-flops 3051, 3052, and 3056 may be reset during the logic high period of the first window clock WD1.

From the logic low period of the first window clock WD1 during which the reset is released, an output Q19 of the first flip-flop 3051 may transition to logic high at the falling edge of the common clock CLK.

Then, an output Q20 of the second flip-flop 3052 may transition to logic high at the rising edge of the common clock CLK. After the rising edge of the common clock CLK, the AND gate 3055 may output logic high to the third input pin. The third flip-flop 3056 may output the output of the AND gate 3055 as a tenth counter signal CNT10 at the next falling edge. The tenth counter signal CNT10 may indicate that three edges corresponding to consecutive logic low, logic high, and logic low have been detected.

According to the above-described embodiments, the sixth triple edge counter 1226 may detect three edges corresponding to consecutive logic low, logic high, and logic low during the logic low period of the first window clock WD1.

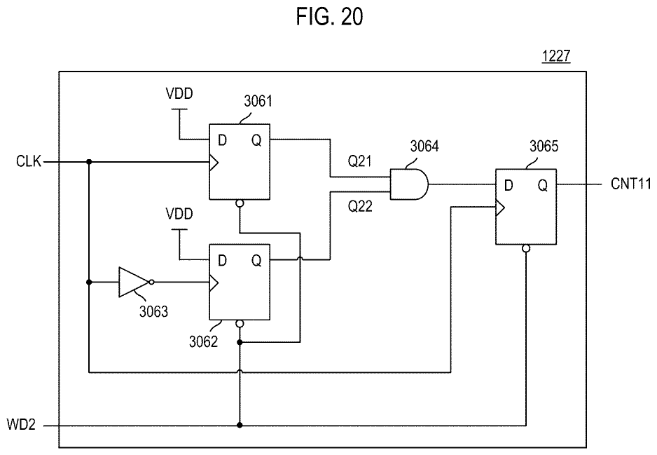

FIG. 20 is a circuit diagram of a seventh triple edge counter according to one or more embodiments.

Referring to FIG. 20, the seventh triple edge counter 1227 according to one or more embodiments may include a first flip-flop 3061, a second flip-flop 3062, a first inverter 3063, an AND gate 3064, and a third flip-flop 3065.

A second window clock WD2 may be provided, without inversion, to a reset pin of each flip-flop included in the seventh triple edge counter 1227.

The operation of the seventh triple edge counter 1227 according to one or more embodiments may be the same as that of the fifth triple edge counter 1225 during the logic low period of the second window clock WD2.

The first, second, and third flip-flops 3061, 3062, and 3065 may be reset during the logic high period of the second window clock WD2.

From the logic low period of the second window clock WD2 during which the reset is released, an output Q22 of the second flip-flop 3062 may transition to logic high at the falling edge of the common clock CLK. Then, an output Q21 of the first flip-flop 3061 may transition to logic high at the rising edge of the common clock CLK.

After the rising edge of the common clock CLK, the AND gate 3064 may output logic high to the third input pin, and the third flip-flop 3065 may output the output of the AND gate 3064 as an eleventh counter signal CNT11 at the next rising edge.

According to the above-described embodiments, the seventh triple edge counter 1227 may detect three edges corresponding to consecutive logic high, logic low, and logic high during the logic low period of the second window clock WD2.

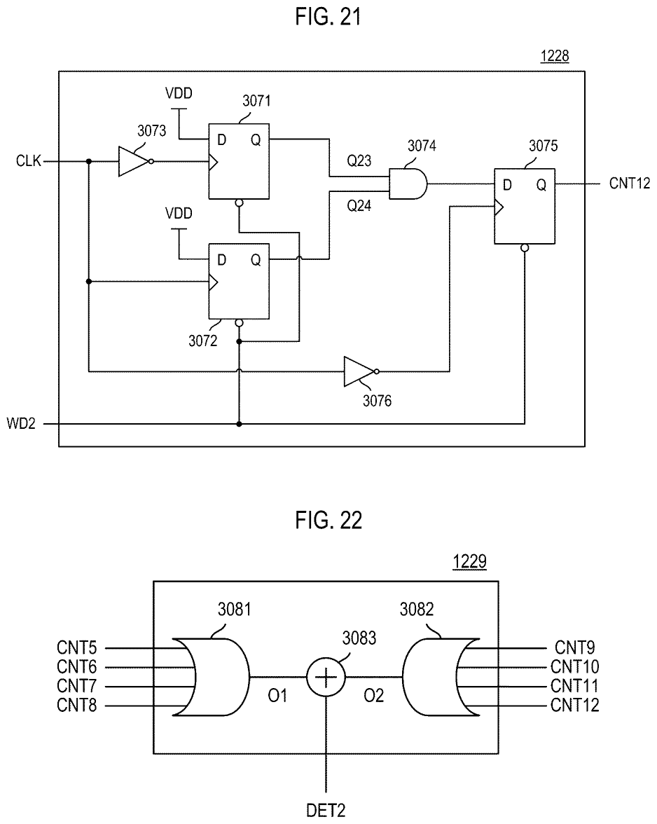

FIG. 21 is a circuit diagram of an eighth triple edge counter according to one or more embodiments.

Referring to FIG. 21, the eighth triple edge counter 1228 according to one or more embodiments may include a first flip-flop 3071, a second flip-flop 3072, a second inverter 3073, a third inverter 3074, an AND gate 3075, and a third flip-flop 3076.

Due to the second inverter 3073 and the third inverter 3074, each flip-flop may be synchronized with an inverted common clock CLK. A second window clock WD2 may be provided, without inversion, to a reset pin of each flip-flop included in the eighth triple edge counter 1228. Thus, each flip-flop may be reset based on the second window clock WD2.

The operation of the eighth triple edge counter 1228 according to one or more embodiments is as follows.

The first, second, and third flip-flops 3071, 3072, and 3076 may be reset during a logic high period of the second window clock WD2.

From the logic low period of the second window clock WD2 during which the reset is released, an output Q23 of the first flip-flop 3071 may transition to logic high at a falling edge of the common clock CLK.

Then, an output Q24 of the second flip-flop 3072 may transition to logic high at a rising edge of the common clock CLK. After the rising edge of the common clock CLK, the AND gate 3075 may output logic high to a third input pin. The third flip-flop 3076 may output the output of the AND gate 3075 as a twelfth counter signal CNT12 at the next falling edge. The twelfth counter signal CNT12 may indicate that three edges corresponding to consecutive logic low, logic high, and logic low have been detected.

According to the above-described embodiments, the eighth triple edge counter 1228 may detect three edges corresponding to consecutive logic low, logic high, and logic low during the logic low period of the second window clock WD2.

FIG. 22 is a circuit diagram of a second logic circuit according to one or more embodiments.

Referring to FIG. 22, the second logic circuit 1229 according to one or more embodiments may include a first OR gate 3081, a second OR gate 3082, and an OR operator 3083.

The first OR gate 3081 may receive the fifth to eighth counter signals CNT5 to CNT8 and performs an OR operation on the fifth to eighth counter signals CNT5 to CNT8. The second OR gate 3082 may receive the ninth to twelfth counter signals CNT9 to CNT12 and performs an OR operation on the ninth to twelfth counter signals CNT9 to CNT12. The fifth to twelfth counter signals CNT5 to CNT12 may indicate that a frequency increase or glitch has occurred in the common clock CLK, at a specific logic level (for example, logic high).

When the specific logic level is high, the output O1 of the first OR gate 3081 may be high even if only one of the fifth to eighth counter signals CNT5 to CNT8 is high. Similarly, the output O2 of the second OR gate 3082 may be high even if only one of the ninth to twelfth counter signals CNT9 to CNT12 is high.

The OR operator 3083 may output a second detection signal DET2 indicating that a fault has occurred when at least one of the first OR gate 3081 or the second OR gate 3082 outputs logic high (for example, when a fault is detected in at least one of a logic high period or a logic low period).

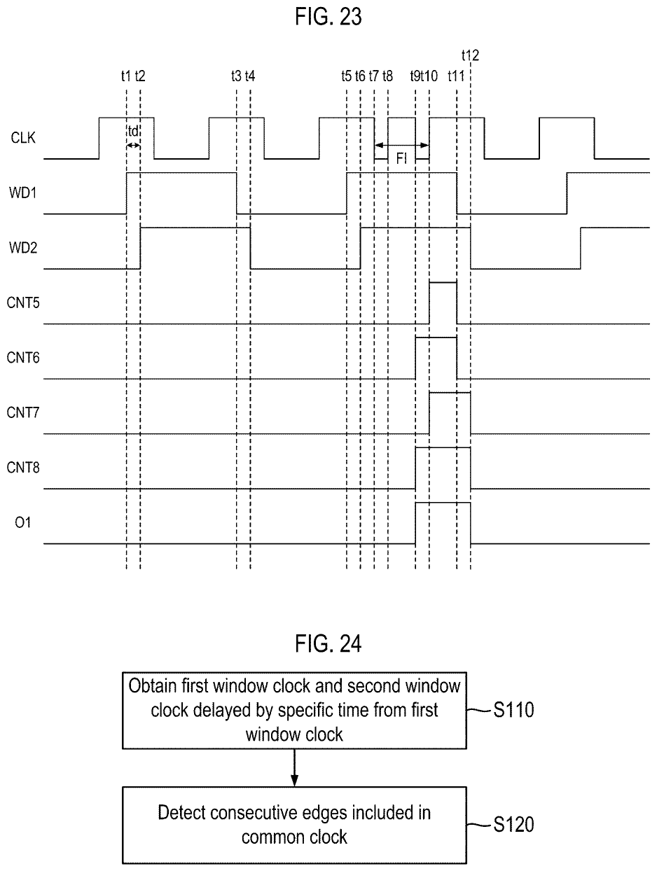

FIG. 23 is a timing diagram of a glitch detection operation during a logic high period of the second detection circuit according to one or more embodiments. In FIG. 23, a first triple edge counter 1221 corresponds to the one illustrated in FIG. 14, a second triple edge counter 1222 corresponds to the one illustrated in FIG. 15, a third triple edge counter 1223 corresponds to the one illustrated in FIG. 16, and a fourth triple edge counter 1224 corresponds to the one illustrated in FIG. 17.

Referring to FIG. 14 to FIG. 17, FIG. 22, and FIG. 23, a delay of td, defined as a period from t1 to t2, may be applied between the first window clock WD1 and the second window clock WD2.

Two consecutive edges of the common clock CLK are present in both the logic high period of the first window clock WD1 corresponding to a period from t1 to t3 and the logic high period of the second window clock WD2 corresponding to a period from t2 to t4. Therefore, the fifth to eighth counter signals CNT5 to CNT8 may all output logic low.

Then, the reset state of the first triple edge counter 1221 and the second triple edge counter 1222 may be released during a period from t5 to t11, and the reset state of the third triple edge counter 1223 and the fourth triple edge counter 1224 may be released during a period from t6 to t12.

A glitch may occur in a fault interval FI corresponding to a period from t7 to t10.

According to the above-described embodiments, the first triple edge counter 1221 and the third triple edge counter 1223 may count the falling edge of the common clock CLK at t7, and may sequentially count the rising edges of the common clock CLK at t8 and t10. Thus, the fifth counter signal CNT5 and the seventh counter signal CNT7 may transition to logic high at t10.

The second triple edge counter 1222 and the fourth triple edge counter 1224 may count the falling edge of the common clock CLK at t7, the rising edge of the common clock CLK at t8, and the falling edge of the common clock CLK at t9. Thus, the sixth counter signal CNT6 and the eighth counter signal CNT8 may transition to logic high at t9.

As the logic high period of the first window clock WD1 ends at t11, the fifth counter signal CNT5 and the seventh counter signal CNT7 may transition to logic low at t11. As the logic high period of the second window clock WD2 ends at t12, the sixth counter signal CNT6 and the eighth counter signal CNT8 may transition to logic low at t12.

The output O1 of the first OR gate may be high during a period from t9 to t12.

As illustrated in the drawing, the second detection circuit 1220 according to one or more embodiments may detect a fault within a single cycle of the window clocks.

FIG. 24 may be a flowchart illustrating a method of a detection device according to one or more embodiments.

Referring to FIG. 24, in operation S110, the detection device may obtain a first window clock signal and a second window clock signal which is delayed by a specific amount of time relative to the first window clock.

In operation S120, the detection device may detect consecutive signal edges included in a common clock from logic high periods and logic low periods of the first window clock and the second window clock obtained in operation S110. Operation S120 may further include detecting two consecutive signal edges and detecting three consecutive signal edges of the common clock CLK.

The above-described method enables the detection device to detect various types of faults for the common clock.

As set forth above, according to example embodiments, a clock fault detection device and a clock fault detection method for detecting various types of clock faults may be provided.

While various embodiments have been shown and described above, it will be apparent to those skilled in the art that modifications and variations could be made without departing from the scope of the present inventive concept as defined by the appended claims.

1. A detection device comprising:
a window clock output circuit configured to obtain a clock signal having a first signal period and configured to output:
a first window clock signal having a second signal period, and
a second window clock signal delayed, by a time delay amount, relative to the first window clock signal and having a signal period equal to the second signal period; and
a defect detection circuit configured to detect consecutive signal edges of the clock signal using logic high periods and logic low periods of the first and second window clock signals,
wherein the second signal period is greater than the first signal period.

2. The detection device of claim 1, wherein:
the second signal period is defined to be less than twice the first signal period.

3. The detection device of claim 1, wherein:
each of the logic high periods and logic low periods have a first duration, and
the time delay amount is greater than a minimum threshold time and less than the first duration.

4. The detection device of claim 3, wherein:
the minimum threshold time is equal to an amount of time occurring between a first falling edge included in a first cycle of the clock signal under normal clock signal conditions and a second falling edge of a comparison window signal, the second falling edge being a falling edge out of a plurality of falling edges of the comparison window signal that occurs closest in time to the first falling edge; and
the comparison window signal has a rising edge at a time point corresponding to a third falling edge of the clock signal under normal clock signal conditions, the third falling edge included in a second cycle of the clock signal which occurs immediately prior to the first cycle.

5. The detection device of claim 4, wherein:
the comparison window signal is the first window clock signal.

6. The detection device of claim 1, wherein:
the defect detection circuit comprises:
a first detection circuit configured to detect two consecutive signal edges in the clock signal by using the logic high periods and the logic low periods; and
a second detection circuit configured to detect three or more consecutive signal edges in the clock signal using the logic high periods and the logic low periods.

7. The detection device of claim 6, wherein:
the first detection circuit is configured to output a first detection signal indicating that a pulse loss or a frequency decrease has been detected from the clock signal when at least one of the following conditions is satisfied: a failure to detect the two consecutive edges of the clock signal during both of one of the logic high periods of the first window clock signal and one of the logic high periods of the second window clock signal, or a failure to detect the two consecutive signal edges of the clock signal during both of one of the logic low periods of the first window clock signal and one of the logic low periods of the second window clock signal.

8. The detection device of claim 6, wherein:
the second detection circuit is configured to output a second detection signal indicating that a glitch or a frequency increase has been detected from the clock signal when the three consecutive signal edges of the clock signal are successfully detected during at least one of the logic high period of the first window clock signal, the logic high period of the second window clock signal, the logic low period of the first window clock signal, or the logic low period of the second window clock signal.

9. The detection device of claim 6, wherein:
the first detection circuit comprises:
a first double edge counter configured to count the two consecutive signal edges of the clock signal during the logic high period of the first window clock signal;
a second double edge counter configured to count the two consecutive signal edges of the clock signal during the logic high period of the second window clock signal;
a third double edge counter configured to count the two consecutive signal edges of the clock signal during the logic low period of the first window clock signal;
a fourth double edge counter configured to count the two consecutive signal edges of the clock signal during the logic low period of the second window clock signal; and
a first logic circuit configured to output a first detection signal indicating that a pulse loss or a frequency decrease has been detected from the clock signal when at least one of the following conditions is satisfied: a failure to detect the two consecutive signal edges of the clock signal in both the first and second double edge counters, or a failure to detect the two consecutive signal edges of the clock signal in both the third and fourth double edge counters.

10. The detection device of claim 9, wherein:
each of the first to fourth double edge counters comprises:
a first flip-flop comprising a first input pin connected to a supply voltage and configured to operate in synchronization with the clock signal;
a first inverter configured to output an inverted clock signal inverted from the clock signal;
a second flip-flop comprising a second input pin connected to the supply voltage and configured to operate in synchronization with the inverted clock signal;
an AND gate configured to perform an AND operation on outputs of the first flip-flop and the second flip-flop;
a delay circuit commonly connected to a first reset pin of the first flip-flop and a second reset pin of the second flip-flop; and
a third flip-flop comprising a third input pin connected to an output of the AND gate and configured to operate in synchronization with the first window clock signal, the second window clock signal, a first inverted window clock signal inverted from the first window clock signal, or a second inverted window clock signal inverted from the second window clock signal.

11. The detection device of claim 10, wherein:
each of the first double edge counter and the second double edge counter further comprises:
a second inverter configured to output the first inverted window clock signal or the second inverted window clock signal to the third flip-flop and the delay circuit;
wherein the delay circuit and the third flip-flop of the third double edge counter are each configured to receive the first window clock signal; and
wherein the delay circuit and the third flip-flop of the fourth double edge counter are configured to receive the second window clock signal.

12. The detection device of claim 10, wherein:
the third flip-flop is configured to operate in synchronization with the first window clock signal, the second window clock signal, a first inverted window clock signal inverted from the first window clock signal, or a second inverted window clock signal inverted from the second window clock signal.

13. The detection device of claim 6, wherein:
the second detection circuit comprises:
a first triple edge counter and a second triple edge counter configured to detect three or more consecutive signal edges of the clock signal during the logic high period of the first window clock signal;
a third triple edge counter and a fourth triple edge counter configured to detect three or more consecutive signal edges of the clock signal during the logic high period of the second window clock signal;
a fifth triple edge counter and a sixth triple edge counter configured to count three or more consecutive signal edges of the clock signal during the logic low period of the first window clock signal;
a seventh triple edge counter and an eighth triple edge counter configured to count three or more consecutive signal edges of the clock signal during the logic low period of the second window clock signal; and
a second logic circuit configured to output a second detection signal indicating that a glitch or a frequency increase has been detected from the clock signal when the three consecutive signal edges of the clock signal are successfully detected in at least one of the first to eighth triple edge counters.

14. The detection device of claim 13, wherein:
each of the first to eighth triple edge counters comprises:
a first flip-flop comprising a first input pin connected to a supply voltage and configured to operate in synchronization with the clock signal or an inverted clock signal inverted from the clock signal;
a second flip-flop comprising a second input pin connected to the supply voltage and configured to operate in synchronization with the clock signal or the inverted clock signal;
an AND gate configured to perform an AND operation on outputs of the first flip-flop and the second flip-flop; and
a third flip-flop comprising a third input pin connected to an output of the AND gate and configured to operate in synchronization with the clock signal or the inverted clock signal.

15. The detection device of claim 14, wherein:
each of the first, third, fifth, and seventh triple edge counters further comprises:
a first inverter configured to output the inverted clock signal to the second flip-flop; and
each of the second, fourth, sixth, and eighth triple edge counters further comprises:
a second inverter configured to output the inverted clock signal to the first flip-flop; and
a third inverter configured to output the inverted clock signal to the third flip-flop.

16. The detection device of claim 15, wherein:
each of the first to fourth triple edge counters further comprises:
a fourth inverter configured to output a first inverted window clock signal, inverted from the first window clock signal, or a second inverted window clock signal, inverted from the second window clock signal, to a first reset pin of the first flip-flop, a second reset pin of the second flip-flop, and a third reset pin of the third flip-flop;
the first window clock signal is provided to the first reset pin of the first flip-flop, the second reset pin of the second flip-flop, and the third reset pin of the third flip-flop included in the fifth and sixth triple edge counters; and
the second window clock signal is provided to the first reset pin of the first flip-flop, the second reset pin of the second flip-flop, and the third reset pin of the third flip-flop included in the seventh and eighth triple edge counters.

17. The detection device of claim 6, wherein:
the first detection circuit is configured to detect a fault within a single cycle of the first or second window clock signals.

18. A method of a detection device, the method comprising:
obtaining a clock signal having a first signal period;
obtaining a first window clock signal having a second signal period that is greater than the first signal period of the clock signal, and a second window clock signal having a signal period equal to the second signal period, the second window clock signal delayed by a time delay amount relative to the first window clock signal; and
detecting consecutive signal edges included in the clock signal using logic high periods and logic low periods of the first and second window clock signals.

19. The method of claim 18, wherein:
the second signal period is less than twice the first signal period,
each of the logic high periods and logic low periods have a first duration, and
the time delay amount is greater than a minimum threshold time and less than the first duration.

20. A detection device comprising:
a first detection circuit configured to:
obtain a clock signal, a first window clock signal, and a second window clock signal, and to detect two consecutive signal edges in the clock signal using logic high periods and logic low periods of the first and second window clock signals; and
a second detection circuit configured to obtain the clock signal, the first window clock signal, and the second window clock signal and to detect three or more consecutive signal edges in the clock signal using the logic high periods and the logic low periods of the first and second window clock signals,
wherein the clock signal has a first signal period, the first window clock signal has a second signal period, and the second window clock signal has a signal period equal to the second signal period,
wherein the second window clock signal is delayed relative to the first window clock signal by a time delay amount,
and
wherein the second signal period is greater than the first signal period.

21-23. (canceled)
